(19) United States
(12) Patent Application Publication
(10) Pub. No.: US 2025/0306115 A1
(43) Pub. Date: Oct. 2, 2025

(54) STATE OF CHARGE ESTIMATION FOR MIXED CHEMISTRY BATTERIES

(71) Applicant: GM Global Technology Operations LLC, Detroit, MI (US)

(72) Inventors: Jian Yao, Shanghai (CN); Jun-Mo Kang, Ann Arbor, MI (US); Chengwu Duan, Shanghai (CN); Shuonan Xu, Suzhou (CN); Mohamed Kamel, Birmingham, MI (US); Zhenwen Hu, Shanghai (CN)

(21) Appl. No.: 18/624,707

(22) Filed: Apr. 2, 2024

(30) Foreign Application Priority Data
Mar. 28, 2024 (CN) 202410372355.7

(51) Int. Cl. G01R 31/388; B60L 58/22; G01R 31/392; G01R 31/396

(52) U.S. Cl. CPC G01R 31/388; B60L 58/22; G01R 31/392; G01R 31/396; B60L 2210/10

(57) ABSTRACT

A method for determining battery cell state of charge (SOC) may include determining a first battery cell effective capacity of a first battery cell. The method further may include determining a first battery cell SOC of the first battery cell based at least in part on the first battery cell effective capacity. The method further may include determining a second battery cell effective capacity of a second battery cell. The second battery cell is electrically connected in series with the first battery cell. The method further may include determining a second battery cell SOC of the second battery cell based at least in part on the first battery cell SOC, the first battery cell effective capacity, and the second battery cell effective capacity.

### CROSS-REFERENCE TO RELATED APPLICATIONS

This application claims the benefit of foreign priority under 35 U.S.C. § 119 of Chinese patent application number 202410372355.7, filed on Mar. 28, 2024. The contents of this application are incorporated herein by reference in their entirety.

### INTRODUCTION

The present disclosure relates to systems and methods for state of charge estimation for batteries, and more particularly, to systems and methods for state of charge estimation for mixed chemistry batteries.

Rechargeable batteries, such as, for example, lithium-ion batteries, are used in a variety of applications, from electric vehicles to residential batteries and grid-scale applications. An important aspect of the effective and efficient operation of rechargeable battery systems is accurate and reliable determination of battery state of charge (SOC) under various operating conditions. State of charge (SOC) is not a directly measurable characteristic of a battery and must be estimated based on directly measurable characteristics such as battery voltage and current flow. However, with some battery chemistries, the relationship between SOC and directly measurable battery characteristics may be highly non-linear. Mixed battery chemistries may be used to balance tradeoffs between SOC estimation accuracy, battery longevity, and performance. However, variations in aging rates between battery chemistries may cause loss of accuracy over time when using estimating SOC using mixed battery chemistries.

Thus, while battery SOC estimation systems and methods achieve their intended purpose, there is a need for a new and improved system and method for determining battery cell state of charge (SOC) of mixed chemistry batteries which accounts for relative rates of aging of different battery chemistries.

### SUMMARY

According to several aspects, a method for determining battery cell state of charge (SOC) is provided. The method may include determining a first battery cell effective capacity of a first battery cell. The method further may include determining a first battery cell SOC of the first battery cell based at least in part on the first battery cell effective capacity. The method further may include determining a second battery cell effective capacity of a second battery cell. The second battery cell is electrically connected in series with the first battery cell. The method further may include determining a second battery cell SOC of the second battery cell based at least in part on the first battery cell SOC, the first battery cell effective capacity, and the second battery cell effective capacity.

In another aspect of the present disclosure, determining the first battery cell effective capacity further may include determining a first battery cell state of health (SOH) of the first battery cell. Determining the first battery cell effective capacity further may include determining the first battery cell effective capacity using a formula:

C′₁=C₁*SOH_{C}_{₁}

where C′₁ is the first battery cell effective capacity, C₁ is a first battery cell nominal capacity, and SOH_{C}_{₁} is the first battery cell SOH.

In another aspect of the present disclosure, determining the first battery cell SOH further may include measuring an amount of charge transferred to or from the first battery cell while a voltage of the first battery cell changes from a first reference voltage to a second reference voltage. Determining the first battery cell SOH further may include calculating the first battery cell SOH using a formula:

$${SOH}_{{C}_{1}} = \frac{Δ {AH}_{1}^{′}}{Δ {AH}_{1}}$$

where SOH_{C}_{₁} is the first battery cell SOH, ΔAH′₁ is the amount of charge transferred to or from the first battery cell, and ΔAH₁ is a reference amount of charge.

In another aspect of the present disclosure, determining the first battery cell SOC further may include measuring a first battery cell voltage of the first battery cell. Determining the first battery cell SOC further may include determining the first battery cell SOC using a SOC estimation algorithm. The SOC estimation algorithm is configured to receive at least the first battery cell voltage and the first battery cell effective capacity as inputs and provide the first battery cell SOC as an output.

In another aspect of the present disclosure, determining the second battery cell effective capacity further may include charging the first battery cell and the second battery cell until the second battery cell is fully charged. Determining the second battery cell effective capacity further may include determining an amount of charge stored in the first battery cell based on the first battery cell effective capacity and the first battery cell SOC. Determining the second battery cell effective capacity further may include determining the second battery cell effective capacity using a formula:

$${C}_{2}^{′} = {AH}_{1} - {C}_{d}$$

where C′₂ is the second battery cell effective capacity, ΔH₁ is the amount of charge stored in the first battery cell, and C_{d} is a capacity remaining in the first battery cell when the second battery cell is fully discharged.

In another aspect of the present disclosure, determining the second battery cell SOC further may include determining the second battery cell SOC using a formula:

$${SOC}_{{C}_{2}} = \frac{{SOC}_{{C}_{1}} * {C}_{1}^{′} - {C}_{d}}{{C}_{2}^{′}}$$

where SOC_{C}_{₂} is the second battery cell SOC, SOC_{C}_{₁} is the first battery cell SOC, C′₁ is the first battery cell effective capacity, C_{d} is a capacity remaining in the first battery cell when the second battery cell is fully discharged, and C′₂ is the second battery cell effective capacity.

In another aspect of the present disclosure, the method further includes balancing the first battery cell and the second battery cell using an active balancing circuit.

In another aspect of the present disclosure, balancing the first battery cell and the second battery cell further may include comparing the first battery cell SOC to the second battery cell SOC. Balancing the first battery cell and the second battery cell further may include transferring energy from the first battery cell to the second battery cell in response to determining that the second battery cell SOC is less than the first battery cell SOC. Balancing the first battery cell and the second battery cell further may include transferring energy from the second battery cell to the first battery cell in response to determining that the first battery cell SOC is less than the second battery cell SOC.

In another aspect of the present disclosure, determining the second battery cell SOC further may include determining a capacity remaining in the first battery cell when the second battery cell is fully discharged based at least in part on the first battery cell effective capacity and the second battery cell effective capacity using a formula:

$${C}_{d}^{′} = {C}_{1}^{′} - {C}_{2}^{′}$$

where C′_{d} is the capacity remaining in the first battery cell when the second battery cell is fully discharged, C′₁ is the first battery cell effective capacity, and C′₂ is the second battery cell effective capacity.

In another aspect of the present disclosure, determining the second battery cell SOC further may include determining the second battery cell SOC using a formula:

$${SOC}_{{C}_{2}} = \frac{{SOC}_{{C}_{1}} * {C}_{1}^{′} - {C}_{d}^{′}}{{C}_{2}^{′}}$$

where SOC_{C}_{₂} is the second battery cell SOC, SOC_{C}_{₁} is the first battery cell SOC, C′₁ is the first battery cell effective capacity, C′_{d} is a capacity remaining in the first battery cell when the second battery cell is fully discharged, and C′₂ is the second battery cell effective capacity.

According to several aspects, a system for determining battery cell state of charge (SOC) is provided. The system may include a first battery cell having a first cell chemistry. The system further may include a second battery cell electrically connected in series with the first battery cell. The second battery cell has a second cell chemistry. The second cell chemistry is different from the first cell chemistry. The system further may include a power electronics module in electrical communication with the first battery cell and the second battery cell. The power electronics module includes one or more electrical components operable to measure voltage and current flow. The system further may include a controller in electrical communication with the power electronics module. The controller is programmed to determine a first battery cell effective capacity of the first battery cell. The controller is further programmed to determine a first battery cell SOC of the first battery cell based at least in part on the first battery cell effective capacity. The controller is further programmed to determine a second battery cell effective capacity of the second battery cell. The controller is further programmed to determine a second battery cell SOC of the second battery cell based at least in part on the first battery cell SOC, the first battery cell effective capacity, and the second battery cell effective capacity.

In another aspect of the present disclosure, to determine the first battery cell SOC, the controller is further programmed to measure a first battery cell voltage of the first battery cell using the power electronics module. To determine the first battery cell SOC, the controller is further programmed to determine the first battery cell SOC using a SOC estimation algorithm. The SOC estimation algorithm is configured to receive at least the first battery cell voltage and the first battery cell effective capacity as inputs and provide the first battery cell SOC as an output.

In another aspect of the present disclosure, to determine the second battery cell effective capacity, the controller is further programmed to charge the first battery cell and the second battery cell until the second battery cell is fully charged using the power electronics module. To determine the second battery cell effective capacity, the controller is further programmed to determine an amount of charge stored in the first battery cell based on the first battery cell effective capacity and the first battery cell SOC. To determine the second battery cell effective capacity, the controller is further programmed to determine the second battery cell effective capacity using a formula:

$${C}_{2}^{′} = {AH}_{1} - {C}_{d}$$

where C′₂ is the second battery cell effective capacity, AH₁ is the amount of charge stored in the first battery cell, and C_{d} is a capacity remaining in the first battery cell when the second battery cell is fully discharged.

In another aspect of the present disclosure, to determine the second battery cell SOC, the controller is further programmed to determine the second battery cell SOC using a formula:

$${SOC}_{{C}_{2}} = \frac{{SOC}_{{C}_{1}} * {C}_{1}^{′} - {C}_{d}}{{C}_{2}^{′}}$$

where SOC_{C}_{₂} is the second battery cell SOC, SOC_{C}_{₁} is the first battery cell SOC, C′₁ is the first battery cell effective capacity, C_{d} is a capacity remaining in the first battery cell when the second battery cell is fully discharged, and C′₂ is the second battery cell effective capacity.

In another aspect of the present disclosure, the power electronics module further may include a DC/DC converter and a plurality of electrical switches in electrical communication with the DC/DC converter, the first battery cell, the second battery cell, and the controller. An operation of each of the plurality of electrical switches is electrically controllable by the controller. The controller is further programmed to compare the first battery cell SOC to the second battery cell SOC. The controller is further programmed to adjust the operation of one or more of the plurality of switches to transfer energy from the first battery cell to the second battery cell using the DC/DC converter in response to determining that the second battery cell SOC is less than the first battery cell SOC. The controller is further programmed to adjust the operation of one or more of the plurality of switches to transfer energy from the second battery cell to the first battery cell using the DC/DC converter in response to determining that the first battery cell SOC is less than the second battery cell SOC.

In another aspect of the present disclosure, to determine the second battery cell SOC, the controller is further programmed to determine a capacity remaining in the first battery cell when the second battery cell is fully discharged based at least in part on the first battery cell effective capacity and the second battery cell effective capacity using a formula:

$${C}_{d}^{′} = {C}_{1}^{′} - {C}_{2}^{′}$$

where C′_{d} is the capacity remaining in the first battery cell when the second battery cell is fully discharged, C′₁ is the first battery cell effective capacity, and C′₂ is the second battery cell effective capacity.

In another aspect of the present disclosure, to determine the second battery cell SOC, the controller is further programmed to determine the second battery cell SOC using a formula:

$${SOC}_{{C}_{2}} = \frac{{SOC}_{{C}_{1}} * {C}_{1}^{′} - {C}_{d}^{′}}{{C}_{2}^{′}}$$

where SOC_{C}_{₂} is the second battery cell SOC, SOC_{C}_{₁} is the first battery cell SOC, C′₁is the first battery cell effective capacity, C′_{d} is a capacity remaining in the first battery cell when the second battery cell is fully discharged, and C′₂ is the second battery cell effective capacity.

According to several aspects, a method for determining battery cell state of charge (SOC) for a vehicle is provided. The method may include determining a first battery cell state of health (SOH) of a first battery cell. The method further may include determining a first battery cell effective capacity using a formula:

$${C}_{1}^{′} = {C}_{1} * {SOH}_{{C}_{1}}$$

where C′₁ is the first battery cell effective capacity and SOH_{C}_{₁} is the first battery cell SOH. The method further may include charging the first battery cell and a second battery cell until the second battery cell is fully charged. The method further may include determining a first battery cell SOC of the first battery cell when the second battery cell is fully charged based at least in part on the first battery cell effective capacity. The method further may include determining an amount of charge stored in the first battery cell when the second battery cell is fully charged based on the first battery cell effective capacity and the first battery cell SOC. The method further may include determining a second battery cell effective capacity using a formula:

$${C}_{2}^{′} = {AH}_{1} - {C}_{d}$$

where C′₂ is the second battery cell effective capacity, AH₁ is the amount of charge stored in the first battery cell, and C_{d} is a capacity remaining in the first battery cell when the second battery cell is fully discharged. The second battery cell is electrically connected in series with the first battery cell. The method further may include determining a second battery cell SOC of the second battery cell based at least in part on the first battery cell SOC, the first battery cell effective capacity, and the second battery cell effective capacity. The method further may include balancing the first battery cell and the second battery cell.

In another aspect of the present disclosure, determining the second battery cell SOC further may include determining a capacity remaining in the first battery cell when the second battery cell is fully discharged based at least in part on the first battery cell effective capacity and the second battery cell effective capacity using a formula:

$${C}_{d}^{′} = {C}_{1}^{′} - {C}_{2}^{′}$$

where C′_{d} is the capacity remaining in the first battery cell when the second battery cell is fully discharged, C′₁ is the first battery cell effective capacity, and C′₂ is the second battery cell effective capacity. Determining the second battery cell SOC further may include determining the second battery cell SOC using a formula:

$${SOC}_{{C}_{2}} = \frac{{SOC}_{{C}_{1}} * {C}_{1}^{′} - {C}_{d}^{′}}{{C}_{2}^{′}}$$

where SOC_{C}_{₂} is the second battery cell SOC, SOC_{C}_{₁} is the first battery cell SOC, C′₁ is the first battery cell effective capacity, C′_{d} is a capacity remaining in the first battery cell when the second battery cell is fully discharged, and C′₂ is the second battery cell effective capacity.

In another aspect of the present disclosure, balancing the first battery cell and the second battery cell further may include comparing the first battery cell SOC to the second battery cell SOC. Balancing the first battery cell and the second battery cell further may include transferring energy from the first battery cell to the second battery cell in response to determining that the second battery cell SOC is less than the first battery cell SOC. Balancing the first battery cell and the second battery cell further may include transferring energy from the second battery cell to the first battery cell in response to determining that the first battery cell SOC is less than the second battery cell SOC.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

The drawings described herein are for illustration purposes only and are not intended to limit the scope of the present disclosure in any way.

FIG. 1 is a schematic diagram of a system for determining battery cell state of charge (SOC), according to an exemplary embodiment;

FIG. 2A is a schematic diagram of a power electronics module, according to a first exemplary embodiment;

FIG. 2B is a schematic diagram of a power electronics module, according to a second exemplary embodiment;

FIG. 3 is a flowchart of a method for determining battery cell state of charge (SOC), according to an exemplary embodiment; and

FIG. 4 is a flowchart of a method for actively balancing a first battery cell and a second battery cell, according to an exemplary embodiment.

### DETAILED DESCRIPTION

The following description is merely exemplary in nature and is not intended to limit the present disclosure, application, or uses.

In aspects of the present disclosure, use of mixed chemistry batteries is advantageous to increase the accuracy of state of charge (SOC) estimation while maintaining high battery performance and long lifespan, as discussed in, for example, U.S. application Ser. No. 18/363,876, titled “LOW TEMPERATURE STATE-OF-CHARGE CORRECTION FOR A MIXED CHEMISTRY BATTERY”, filed on Aug. 2, 2023, the entire contents of which is hereby incorporated by reference. Characteristics of mixed chemistry batteries may vary based on relative rates of aging of different battery chemistries. Accordingly, the present disclosure provides a new and improved system method for determining battery cell state of charge (SOC) of mixed chemistry batteries which accounts for relative rates of aging of different battery chemistries.

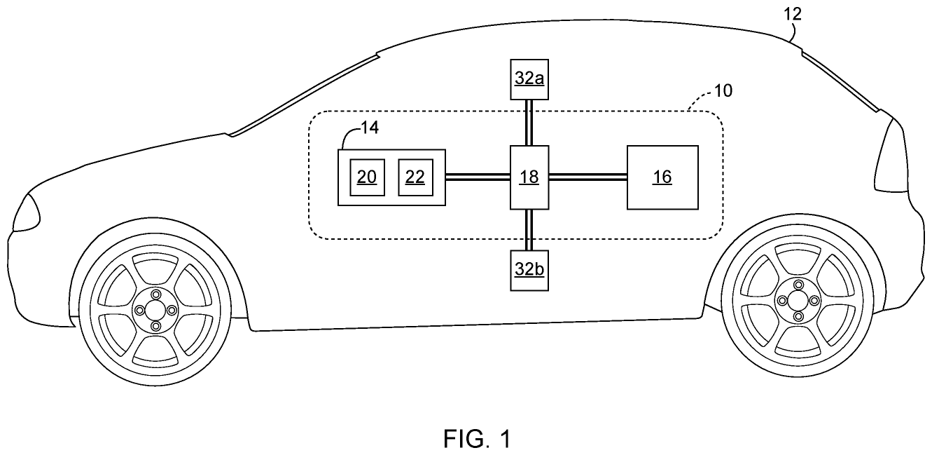

Referring to FIG. 1, a system for determining battery cell state of charge (SOC) is illustrated and generally indicated by reference number 10. The system 10 is shown with an exemplary vehicle 12. While a passenger vehicle is illustrated, it should be appreciated that the vehicle 12 may be any type of vehicle without departing from the scope of the present disclosure. The system 10 generally includes a controller 14, a battery module 16, and a power electronics module 18.

The controller 14 is used to implement a method 100 for determining battery cell state of charge (SOC), as will be described below. The controller 14 includes at least one processor 20 and a non-transitory computer readable storage device or media 22. The processor 20 may be a custom made or commercially available processor, a central processing unit (CPU), a graphics processing unit (GPU), an auxiliary processor among several processors associated with the controller 14, a semiconductor-based microprocessor (in the form of a microchip or chip set), a macroprocessor, a combination thereof, or generally a device for executing instructions.

The computer readable storage device or media 22 may include volatile and nonvolatile storage in read-only memory (ROM), random-access memory (RAM), and keep-alive memory (KAM), for example. KAM is a persistent or non-volatile memory that may be used to store various operating variables while the processor 20 is powered down. The computer-readable storage device or media 22 may be implemented using a number of memory devices such as PROMs (programmable read-only memory), EPROMs (electrically PROM), EEPROMs (electrically erasable PROM), flash memory, or another electric, magnetic, optical, or combination memory devices capable of storing data, some of which represent executable instructions used by the controller 14 to determine battery cell state of charge and/or interface with the power electronics module 18 and the battery module 16. In an exemplary embodiment, the controller 14 functions as part of a battery management system (BMS), and the media 22 further includes executable instructions used by the controller 14 to manage an operation of the battery module 16 and monitor battery characteristics such as a state of charge (SOC), state of health (SOH), temperature, and/or the like. It should be understood that the controller 14 may also consist of multiple controllers which are in electrical communication with each other.

The controller 14 is in electrical communication with the power electronics module 18. In an exemplary embodiment, the electrical communication is established using, for example, a CAN network, a FLEXRAY network, a local area network (e.g., WiFi, ethernet, and the like), a serial peripheral interface (SPI) network, or the like. It should be understood that various additional wired and wireless techniques and communication protocols for communicating with the controller 14 are within the scope of the present disclosure. It should further be understood that, in the scope of the present disclosure, electrical communication also includes power and/or energy transfer between electrical devices (e.g., using conducting wires and/or wireless power transmission techniques).

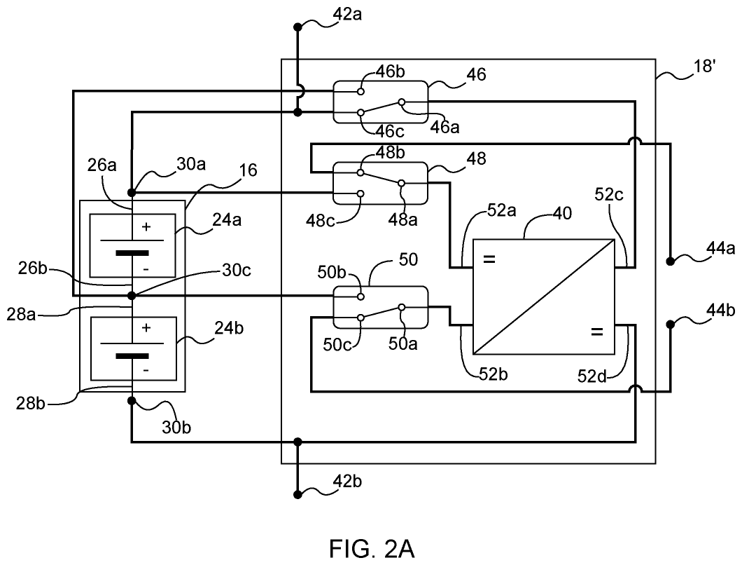

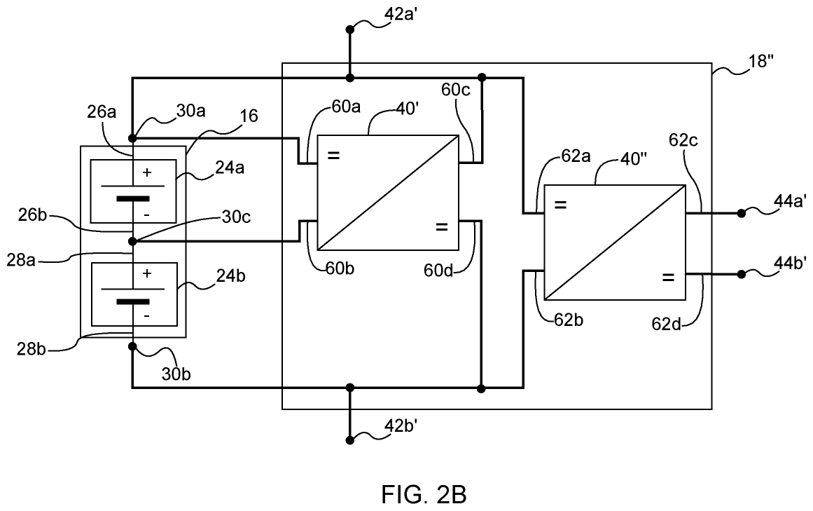

The battery module 16 is used to store electrical energy for use by electrical systems of the vehicle 12. In an exemplary embodiment, the battery module 16 includes a first battery cell 24a (FIGS. 2A-2B) and a second battery cell 24b (FIGS. 2A-2B) electrically connected in series. The first battery cell 24a has a first battery cell positive terminal 26a (FIGS. 2A-2B) and a first battery cell negative terminal 26b (FIGS. 2A-2B). The second battery cell 24b has a second battery cell positive terminal 28a (FIGS. 2A-2B) and a second battery cell negative terminal 28b (FIGS. 2A-2B). The first battery cell negative terminal 26b and the second battery cell positive terminal 28a are in electrical communication, forming a series connection between the first battery cell 24a and the second battery cell 24b. It should be understood that the battery module 16 may include a plurality of battery cells electrically connected in series and/or parallel.

In an exemplary embodiment, the first battery cell 24a and the second battery cell 24b are lithium-ion battery cells. The first battery cell 24a has a first cell chemistry (e.g., lithium nickel manganese cobalt oxide (NCM)) and the second battery cell 24b has a second cell chemistry (e.g., lithium iron phosphate (LiFePO4)). In a non-limiting example, it is desirable that the first cell chemistry and the second cell chemistry are chosen such that the first battery cell 24a has a relatively linear open-circuit voltage (OCV) vs. state of charge (SOC) curve compared to the open-circuit voltage (OCV) vs. state of charge (SOC) curve of the second battery cell 24b. In a non-limiting example, it is also desirable that the first battery cell 24a have a larger nominal capacity than the second battery cell 24b, as will be discussed in greater detail below. The difference in nominal capacity between the first battery cell 24a and the second battery cell 24b is hereinafter referred to as a buffer capacity.

The battery module 16 has a positive battery module terminal 30a (FIGS. 2A-2B) in electrical communication with the first battery cell positive terminal 26a, a negative battery module terminal 30b (FIGS. 2A-2B) in electrical communication with the second battery cell negative terminal 28b, and an intermediate battery module terminal 30c (FIGS. 2A-2B) in electrical communication with the first battery cell negative terminal 26b and the second battery cell positive terminal 28a. The positive battery module terminal 30a, the negative battery module terminal 30b, and the intermediate battery module terminal 30c are in electrical communication with the power electronics module 18, as will be discussed in greater detail below. In a non-limiting example, the battery module 16 further includes an enclosure configured to protect the first battery cell 24a and the second battery cell 24b from mechanical vibration, water intrusion, and dust intrusion. The enclosure is also configured to provide temperature regulation (e.g., using a liquid cooling system, a resistive heating system, and/or the like).

The power electronics module 18 is used to interface with the battery module 16. In an exemplary embodiment, the power electronics module 18 is operable to facilitate transfer of electrical energy from the battery module 16 to a low voltage electrical system 32a (e.g., lights, infotainment systems, climate control systems, safety systems, and/or the like) and a high voltage electrical system 32b (e.g., one or more electric motors for vehicle propulsion). The power electronics module 18 is further operable to measure voltage and current flow within the battery module 16. The power electronics module 18 is further operable to charge and/or discharge the battery module 16 through connection to an external power source (e.g., a charging station). In another exemplary embodiment, the power electronics module 18 is operable to act as an active balancing circuit to actively balance the first battery cell 24a and the second battery cell 24b of the battery module 16, as will be discussed in greater detail below.

In a non-limiting example, the power electronics module 18 includes power switching components (e.g., electrically controllable switches), power conversion components (e.g., DC/DC converters, inverters, transformers, and/or the like), and/or the like. The power electronics module 18 further includes one or more electrical components operable to measure voltage and current flow. In a non-limiting example, the power electronics module 18 includes an analog to digital converter (ADC), a voltage divider, an operational amplifier, a voltage follower, a shunt resistor, a hall effect current sensor, and/or the like. The one or more electrical components operable to measure voltage and current flow are in electrical communication with the controller 14 to provide measurement data to the controller 14.

Referring to FIG. 2A, a schematic diagram of a first embodiment of the power electronics module 18′ with the battery module 16 is shown. The first embodiment of the power electronics module 18′ includes a first DC/DC converter 40, a positive high voltage terminal 42a, a negative high voltage terminal 42b, a positive low voltage terminal 44a, a negative low voltage terminal 44b, a first electrical switch 46, a second electrical switch 48, and a third electrical switch 50 (hereinafter referred to collectively as the electrical switches 46, 48, 50).

The first DC/DC converter 40 is used to convert voltage levels for the purpose of powering the low voltage electrical system 32a and/or performing active balancing on the first battery cell 24a and the second battery cell 24b. In an exemplary embodiment, the first DC/DC converter 40 includes a first terminal 52a, a second terminal 52b, a third terminal 52c, and a fourth terminal 52d. In an exemplary embodiment, an operation of the first DC/DC converter 40, including, for example, an activation state, a duty cycle, a conversion ratio, a voltage setpoint, and/or the like are controllable by the controller 14 using electrical signals (e.g., analog and/or digital electrical signals).

In an exemplary embodiment, the first DC/DC converter 40 functions to convert a first voltage applied across the first terminal 52a and the second terminal 52b to a second voltage across the third terminal 52c and the fourth terminal 52d. In another exemplary embodiment, the first DC/DC converter 40 functions to convert a first voltage applied across the third terminal 52c and the fourth terminal 52d to a second voltage across the first terminal 52a and the second terminal 52b. The first DC/DC converter 40 transmits power to the first and second terminals 52a, 52b from the third and fourth terminals 52c, 52d and/or from the first and second terminals 52a, 52b to the third and fourth terminals 52c, 52d with a relatively high efficiency (e.g., greater than eighty percent).

In a non-limiting example, the first DC/DC converter 40 is realized as a unidirectional or bidirectional DC/DC converter such as, for example, a buck-boost converter, a buck converter, a boost converter, a single-ended primary inductance converter (SEPIC), and/or the like. It should be understood that the first DC/DC converter 40 may be realized using any circuit topology or architecture operable for DC-to-DC power conversion.

The positive high voltage terminal 42a is connected to the positive battery module terminal 30a. The negative high voltage terminal 42b is connected to the negative battery module terminal 30b. The positive high voltage terminal 42a and the negative high voltage terminal 42b are connected to the high voltage electrical system 32b of the vehicle 12 to supply electrical energy to the high voltage electrical system 32b. The positive low voltage terminal 44a is electrically connected to the second electrical switch 48, as will be discussed in greater detail below. The negative low voltage terminal 44b is electrically connected to the third electrical switch 50, as will be discussed in greater detail below. The positive low voltage terminal 44a and the negative low voltage terminal 44b are connected to the low voltage electrical system 32a of the vehicle 12 to supply electrical energy to the low voltage electrical system 32a.

The electrical switches 46, 48, 50 are used to control connections between the battery module 16 and the first DC/DC converter 40. In an exemplary embodiment, the electrical switches 46, 48, 50 are single pole, double throw (SPDT) electrically controllable switches such as, for example, electromagnetic or solid-state relays, contactors, semiconductor-based switches (e.g., metal-oxide-semiconductor field-effect transistors (MOSFET), insulated-gate bipolar transistors (IGBT), and/or the like), and/or the like. In a non-limiting example, the electrical switches 46, 48, 50 allow a pole terminal to be electrically connected to one of two switched terminals based on a control signal received from, for example, the controller 14.

The first electrical switch 46 has a pole terminal 46a, a first switched terminal 46b and a second switched terminal 46c. The pole terminal 46a is connected to the third terminal 52c of the first DC/DC converter 40. The first switched terminal 46b is connected to the intermediate battery module terminal 30c of the battery module 16. The second switched terminal 46c is connected to the positive battery module terminal 30a of the battery module 16.

The second electrical switch 48 has a pole terminal 48a, a first switched terminal 48b and a second switched terminal 48c. The pole terminal 48a is connected to the first terminal 52a of the first DC/DC converter 40. The first switched terminal 48b is connected to the positive low voltage terminal 44a. The second switched terminal 48c is connected to the positive battery module terminal 30a of the battery module 16.

The third electrical switch 50 has a pole terminal 50a, a first switched terminal 50b and a second switched terminal 50c. The pole terminal 50a is connected to the second terminal 52b of the first DC/DC converter 40. The first switched terminal 50b is connected to the intermediate battery module terminal 30c of the battery module 16. The second switched terminal 50c is connected to the negative low voltage terminal 44b.

The controller 14 operates the first embodiment of the power electronics module 18′ by controlling the operation of the electrical switches 46, 48, 50 to supply electrical energy to the low voltage electrical system 32a of the vehicle 12 or to actively balance the first battery cell 24a and the second battery cell 24b, as will be discussed in greater detail below. To supply electrical energy to the low voltage electrical system 32, the controller 14 controls the operation of the electrical switches 46, 48, 50 such that the pole terminal 46a is connected to the second switched terminal 46c, the pole terminal 48a is connected to the first switched terminal 48b, and the pole terminal 50a is connected to the second switched terminal 50c.

Referring to FIG. 2B, a schematic diagram of a second embodiment of the power electronics module 18″ with the battery module 16 is shown. The second embodiment of the power electronics module 18″ includes a second DC/DC converter 40′, a third DC/DC converter 40″, a positive high voltage terminal 42a′, a negative high voltage terminal 42b′, and a positive low voltage terminal 44a′, a negative low voltage terminal 44b′.

The second DC/DC converter 40′ is used to convert voltage levels for the purpose of performing active balancing on the first battery cell 24a and the second battery cell 24b. In an exemplary embodiment, the second DC/DC converter 40′ includes a first terminal 60a, a second terminal 60b, a third terminal 60c, and a fourth terminal 60d. In an exemplary embodiment, an operation of the second DC/DC converter 40′, including, for example, an activation state, a duty cycle, a conversion ratio, a voltage setpoint, and/or the like are controllable by the controller 14 using electrical signals (e.g., analog and/or digital electrical signals).

The first terminal 60a is connected to the positive battery module terminal 30a. The second terminal 60b is connected to the intermediate battery module terminal 30c. The third terminal 60c is connected to the positive battery module terminal 30a. The fourth terminal 60d is connected to the negative battery module terminal 30b.

In an exemplary embodiment, the second DC/DC converter 40′ functions to convert a first voltage applied across the first terminal 60a and the second terminal 60b to a second voltage across the third terminal 60c and the fourth terminal 60d. In another exemplary embodiment, the second DC/DC converter 40′ functions to convert a first voltage applied across the third terminal 60c and the fourth terminal 60d to a second voltage across the first terminal 60a and the second terminal 60b. The second DC/DC converter 40′ transmits power to the first and second terminals 60a, 60b from the third and fourth terminals 60c, 60d and/or from the first and second terminals 60a, 60b to the third and fourth terminals 60c, 60d with a relatively high efficiency (e.g., greater than eighty percent).

In a non-limiting example, the second DC/DC converter 40′ is realized as a unidirectional or bidirectional DC/DC converter such as, for example, a buck-boost converter, a buck converter, a boost converter, a single-ended primary inductance converter (SEPIC), and/or the like. It should be understood that the second DC/DC converter 40′ may be realized using any circuit topology or architecture operable for DC-to-DC power conversion.

The third DC/DC converter 40″ is used to convert voltage levels for the purpose of powering the low voltage electrical system 32a. In an exemplary embodiment, the third DC/DC converter 40″ includes a first terminal 62a, a second terminal 62b, a third terminal 62c, and a fourth terminal 62d. In an exemplary embodiment, an operation of the third DC/DC converter 40″ including, for example, an activation state, a duty cycle, a conversion ratio, a voltage setpoint, and/or the like are controllable by the controller 14 using electrical signals (e.g., analog and/or digital electrical signals).

In an exemplary embodiment, the third DC/DC converter 40″ functions to convert a first voltage applied across the first terminal 62a and the second terminal 62b to a second voltage across the third terminal 62c and the fourth terminal 62d. In another exemplary embodiment, the third DC/DC converter 40″ functions to convert a first voltage applied across the third terminal 62c and the fourth terminal 62d to a second voltage across the first terminal 62a and the second terminal 62b. The third DC/DC converter 40″ transmits power to the first and second terminals 62a, 62b from the third and fourth terminals 62c, 62d and/or from the first and second terminals 62a, 62b to the third and fourth terminals 62c, 62d with a relatively high efficiency (e.g., greater than eighty percent).

The first terminal 62a is connected to the positive battery module terminal 30a. The second terminal 62b is connected to the negative battery module terminal 30b. The third terminal 62c is connected to the positive low voltage terminal 44a′. The fourth terminal 62d is connected to the negative low voltage terminal 44b′.

In a non-limiting example, the third DC/DC converter 40″ is realized as a unidirectional or bidirectional DC/DC converter such as, for example, a buck-boost converter, a buck converter, a boost converter, a single-ended primary inductance converter (SEPIC), and/or the like. It should be understood that the third DC/DC converter 40″ may be realized using any circuit topology or architecture operable for DC-to-DC power conversion.

The positive high voltage terminal 42a′ is connected to the positive battery module terminal 30a. The negative high voltage terminal 42b′ is connected to the negative battery module terminal 30b. The positive high voltage terminal 42a′ and the negative high voltage terminal 42b′ are connected to the high voltage electrical system 32b of the vehicle 12 to supply electrical energy to the high voltage electrical system 32b. The positive low voltage terminal 44a′ is electrically connected to the third terminal 62c of the third DC/DC converter 40″, as discussed above. The negative low voltage terminal 44b′ is electrically connected to the fourth terminal 62d of the third DC/DC converter 40″, as discussed above. The positive low voltage terminal 44a′ and the negative low voltage terminal 44b′ are connected to the low voltage electrical system 32a of the vehicle 12 to supply electrical energy to the low voltage electrical system 32a.

The controller 14 operates the second embodiment of the power electronics module 18″ by controlling the operation of the second DC/DC converter 40′ and the third DC/DC converter 40″ to supply electrical energy to the low voltage electrical system 32a of the vehicle 12 and/or to actively balance the first battery cell 24a and the second battery cell 24b, as will be discussed in greater detail below.

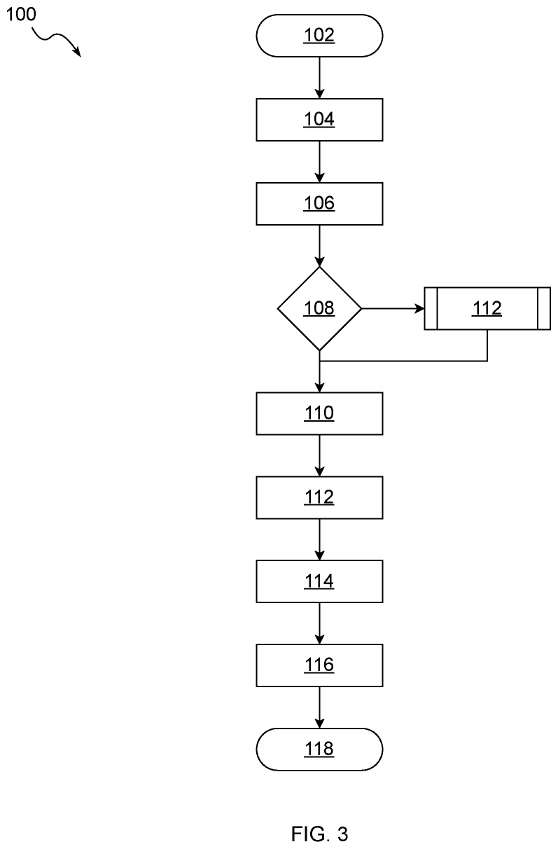

Referring to FIG. 3, a flowchart of the method 100 for determining battery cell state of charge (SOC) is shown. In the scope of the present disclosure, the SOC of a battery cell is defined as the ratio of residual capacity of the battery cell to effective capacity of the battery cell. Residual capacity is defined as a quantity of charge which would be removed from the battery cell if the battery cell were to be brought from its present state to a fully discharged state. Effective capacity is defined as a quantity of charge which would be removed from the battery cell if the battery cell were brought from a fully charged state to the fully discharged state. The effective capacity generally decays over time as the battery cell ages and experiences charge/discharge cycles, as will be discussed in greater detail below.

The method 100 beings at block 102 and proceeds to block 104. At block 104, the controller 14 determines a first battery cell state of health (SOH) of the first battery cell 24a. In the scope of the present disclosure, the SOH of a battery cell is defined as a ratio of the effective capacity of the battery cell to a nominal capacity of the battery cell. The nominal capacity of the battery cell is defined as an ideal quantity of charge which would be removed from a reference battery cell if the reference battery cell were brought from a fully charged state to the fully discharged state, given that that reference battery cell has not experienced aging or charge/discharge cycles. Accordingly, the SOH of a battery cell provides information about the decay of the effective capacity of the battery cell relative to a reference battery cell of the same type, model, form-factor, chemistry, etc. which has not experienced aging or charge/discharge cycles.

In an exemplary embodiment, to determine the first battery cell SOH, the controller 14 uses the power electronics module 18 to measure an amount of charge transferred to or from the first battery cell 24a while a voltage measured across the first battery cell positive terminal 26a and the first battery cell negative terminal 26b changes between a first reference voltage and a second reference voltage.

For example, during a charging process of the battery module 16 the power electronics module 18 monitors the voltage measured across the first battery cell positive terminal 26a and the first battery cell negative terminal 26b. When the voltage reaches the first reference voltage, the power electronics module 18 beings monitoring current flow into the first battery cell 24a and recording the amount of charge transferred to the first battery cell 24a. When the voltage reaches the second reference voltage, the power electronics module 18 stops monitoring the current flow into the first battery cell 24a and calculates the total amount of charge transferred to the first battery cell 24a while the voltage measured across the first battery cell positive terminal 26a and the first battery cell negative terminal 26b changed from the first reference voltage to the second reference voltage.

In another example, during a discharging process of the battery module 16 the power electronics module 18 monitors the voltage measured across the first battery cell positive terminal 26a and the first battery cell negative terminal 26b. When the voltage reaches the second reference voltage, the power electronics module 18 beings monitoring current flow out of the first battery cell 24a and recording the amount of charge transferred out of the first battery cell 24a. When the voltage reaches the first reference voltage, the power electronics module 18 stops monitoring the current flow out of the first battery cell 24a and calculates the total amount of charge transferred out of the first battery cell 24a while the voltage measured across the first battery cell positive terminal 26a and the first battery cell negative terminal 26b changed from the second reference voltage to the first reference voltage.

The first battery cell SOH is calculated using a formula:

$${SOH}_{{C}_{1}} = \frac{Δ {AH}_{1}^{′}}{Δ {AH}_{1}} \qquad ( 1 )$$

where SOH_{C}_{₁} is the first battery cell SOH, ΔAH′₁ is the amount of charge transferred to or from the first battery cell 24a while the voltage measured across the first battery cell positive terminal 26a and the first battery cell negative terminal 26b changed between the first reference voltage and the second reference voltage, and ΔAH₁ is a reference amount of charge.

The reference amount of charge is determined in a laboratory setting by measuring an amount of charge transferred to or from a reference battery cell while a voltage measured across a reference battery cell positive terminal and a reference battery cell negative terminal changes between the first reference voltage and the second reference voltage. The reference battery cell has similar parameters (e.g., cell type, cell chemistry, cell nominal capacity, etc.) to the first battery cell 24a, but a known 100% SOH. The first reference voltage and the second reference voltage are chosen based on a nominal operating voltage range of the first battery cell 24a and the reference battery cell. After block 104, the method 100 proceeds to block 106.

At block 106, the controller 14 determines a first battery cell effective capacity using a formula:

$${C}_{I}^{′} = {C}_{1} * {SOH}_{{C}_{1}} \qquad ( 2 )$$

where C′₁ is the first battery cell effective capacity, C₁ is a first battery cell nominal capacity (e.g., provided by the manufacturer of the first battery cell 24a), and SOH_{C}_{₁} is the first battery cell SOH determined at block 104. After block 106, the method 100 proceeds to block 108.

At block 108, the method 100 varies based on a buffer capacity configuration of the battery module 16. In the scope of the present disclosure, the buffer capacity configuration includes one of a topside buffer capacity configuration and a non-topside buffer configuration. In the topside buffer configuration, the first battery cell 24a and the second battery cell 24b are configured such that, during the entire usable life of the second battery cell 24b, a first battery cell SOC (i.e., a state of charge of the first battery cell 24a) is always less than 100% when a second battery cell SOC (i.e., a state of charge of the second battery cell 24b) is 100%. In the non-topside buffer configuration, the first battery cell 24a and the second battery cell 24b are configured such that, during at least a portion of the usable life of the second battery cell 24b, the first battery cell SOC reaches 100% when the second battery cell SOC is less than or equal to 100%.

If the buffer capacity configuration is the topside buffer capacity configuration, the method 100 proceeds to block 110, as will be discussed in greater detail below. If the buffer capacity configuration is the non-topside buffer capacity configuration, the method 100 proceeds to block 112.

At block 112, the controller 14 uses the power electronics module 18 to actively balance the first battery cell 24a and the second battery cell 24b, as will be discussed in greater detail below. After block 112, the method 100 proceeds to block 110.

At block 110, the controller 14 determines the first battery cell SOC. In an exemplary embodiment, to determine the first battery cell SOC, the controller 14 first uses the power electronics module 18 to charge the battery module 16 until at least one of the first battery cell SOC and the second battery cell SOC is equal to 100%. The controller 14 then uses the power electronics module 18 to measure a first battery cell voltage across the first battery cell positive terminal 26a and the first battery cell negative terminal 26b. The controller 14 then uses a SOC estimation algorithm to determine the first battery cell SOC. In an exemplary embodiment, the SOC estimation algorithm utilizes mathematical and/or statistical models, such as equivalent circuit models, Kalman filters, and/or the like, to estimate the first battery cell SOC accurately. In a non-limiting example, the SOC estimation algorithm includes features such as open-circuit voltage (OCV) estimation, coulomb counting, and model-based adaptive filtering.

The SOC estimation algorithm is configured to receive the first battery cell voltage determined at block 110 and the first battery cell effective capacity determined at block 106 as inputs and provide the first battery cell SOC as an output. In a non-limiting example, the SOC estimation algorithm is further configured to receive additional information, such as, for example, a temperature of the first battery cell 24a, as inputs. The SOC estimation algorithm functions by processing the inputs and applying algorithms to predict the first battery cell SOC. Coulomb counting measures the charge or discharge current over time to estimate the change in stored energy, while OCV estimation predicts the battery's voltage at various SOC levels. Model-based adaptive filtering integrates these measurements with battery characteristics to improve accuracy and robustness. After block 110, the method 100 proceeds to block 112.

At block 112, the controller 14 determines an amount of charge stored in the first battery cell 24a. In an exemplary embodiment, to determine the amount of charge stored in the first battery cell 24a, the controller 14 uses a formula:

$$A {H}_{1} = {C}_{I}^{′} * {SOC}_{{C}_{1}} \qquad ( 3 )$$

where AH₁ is the amount of charge stored in the first battery cell 24a, C′₁ is the first battery cell effective capacity determined at block 106, and SOC_{C}_{₁} is the first battery cell SOC determined at block 110. After block 112, the method 100 proceeds to block 114.

At block 114, the controller 14 determines a second battery cell effective capacity. In an exemplary embodiment, to determine the second battery cell effective capacity, the controller 14 uses a formula:

$${C}_{2}^{′} = {AH}_{1} - {C}_{d} \qquad ( 4 )$$

where C′₂ is the second battery cell effective capacity, AH₁ is the amount of charge stored in the first battery cell determined at block 112, and C_{d} is a capacity remaining (i.e., residual capacity) in the first battery cell 24a when the second battery cell 24b is fully discharged (i.e., the second battery cell SOC is 0%), hereinafter referred to as a bottom side buffer capacity. In a non-limiting example, the bottom side buffer capacity is determined experimentally. In another non-limiting example, the bottom side buffer capacity is calculated based on the buffer capacity and the buffer capacity configuration. After block 114, the method 100 proceeds to block 116.

At block 116, the controller 14 determines a second battery cell SOC. In a first exemplary embodiment, the controller 14 determines the second battery cell SOC using a first formula:

$${SOC}_{{C}_{2}} = \frac{{SOC}_{{C}_{1}} * {C}_{1}^{′} - {C}_{d}}{{C}_{2}^{′}} \qquad ( 5 )$$

where SOC_{C}_{₂} is the second battery cell SOC, SOC_{C}_{₁} is the first battery cell SOC determined at block 110, C′₁ is the first battery cell effective capacity determined at block 106, C_{d} is the bottom side buffer capacity, and C′₂ is the second battery cell effective capacity determined at block 114. The first formula is used when the buffer capacity configuration is the topside buffer capacity configuration.

In a second exemplary embodiment, the controller 14 determines the second battery cell SOC using a second formula:

$${SOC}_{{C}_{2}} = \frac{{SOC}_{{C}_{1}} * {C}_{1}^{′} - {C}_{d}^{′}}{{C}_{2}^{′}} \qquad ( 6 )$$

$${C}_{d}^{′} = {C}_{d} - Δ = {C}_{d} - ( {C}_{2}^{′} + {C}_{d} - {C}_{1}^{′} ) = {C}_{1}^{′} - {C}_{2}^{′} \qquad ( 7 )$$

where SOC_{C}_{₂} is the second battery cell SOC, SOC_{C}_{₁} is the first battery cell SOC determined at block 110, C′₁ is the first battery cell effective capacity determined at block 106, C′_{d} is an effective bottom side buffer capacity, C_{d} is the bottom side buffer capacity, Δ is a difference between the residual capacity of the second battery cell 24a and the residual capacity of the first battery cell 24a when the first battery cell SOC is 100% and the second battery cell SOC is 100%, and C′₂ is the second battery cell effective capacity determined at block 114.

The difference A between the bottom side buffer capacity C_{d} and the effective bottom side buffer capacity C′_{d} is caused by a difference in a rate of SOH degradation between the first battery cell 24a and the second battery cell 24b when the buffer capacity configuration is the non-topside buffer capacity configuration. Accordingly, the second formula is used when the buffer capacity configuration is the non-topside buffer capacity configuration. After block 116, the method proceeds to enter a standby state at block 118.

In an exemplary embodiment, the controller 14 repeatedly exits the standby state 118 and restarts the method 100 at block 102. In a non-limiting example, the controller 14 exits the standby state 118 and restarts the method 100 on a timer, for example, every three hundred milliseconds.

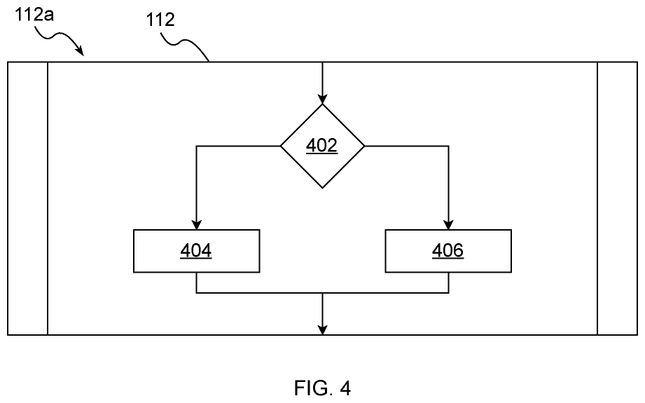

Referring to FIG. 4, a flowchart of an exemplary embodiment 112a of block 112 (i.e., a method for actively balancing the first battery cell 24a and the second battery cell 24b) is shown. The exemplary embodiment 112a begins at block 402. At block 402, the controller 14 compares the first battery cell SOC to the second battery cell SOC. If the second battery cell SOC is less than the first battery cell SOC, the exemplary embodiment 112a proceeds to block 404. If the first battery cell SOC is less than the second battery cell SOC, the exemplary embodiment 112a proceeds to block 406.

At block 404, the controller 14 uses the power electronics module 18 to transfer energy from the first battery cell 24a to the second battery cell 24b. In an exemplary embodiment including the first embodiment of the power electronics module 18′, the controller 14 controls the operation of the electrical switches 46, 48, 50 such that the pole terminal 46a is connected to the first switched terminal 46b, the pole terminal 48a is connected to the second switched terminal 480, and the pole terminal 50a is connected to the first switched terminal 50b. The controller 14 also controls the first DC/DC converter 40 to facilitate energy transfer from the first battery cell 24a to the second battery cell 24b. Energy transfer is terminated when the first battery cell SOC is equal to the second battery cell SOC.

In an exemplary embodiment including the second embodiment of the power electronics module 18″, the controller 14 controls the second DC/DC converter 40′ to facilitate energy transfer from the first battery cell 24a to the second battery cell 24b. Energy transfer is terminated when the first battery cell SOC is equal to the second battery cell SOC.

In another exemplary embodiment, the first battery cell 24a is discharged through a resistor until the first battery cell SOC is equal to the second battery cell SOC. After block 404, the exemplary embodiment 112a is concluded, and the method 100 proceeds as discussed above.

At block 406, the controller 14 uses the power electronics module 18 to transfer energy from the second battery cell 24b to the first battery cell 24a. In an exemplary embodiment including the first embodiment of the power electronics module 18′, the controller 14 controls the operation of the electrical switches 46, 48, 50 such that the pole terminal 46a is connected to the first switched terminal 46b, the pole terminal 48a is connected to the second switched terminal 48c, and the pole terminal 50a is connected to the first switched terminal 50b. The controller 14 also controls the first DC/DC converter 40 to facilitate energy transfer from the second battery cell 24b to the first battery cell 24a. Energy transfer is terminated when the first battery cell SOC is equal to the second battery cell SOC.

In an exemplary embodiment including the second embodiment of the power electronics module 18″, the controller 14 controls the second DC/DC converter 40′ to facilitate energy transfer from the second battery cell 24b to the first battery cell 24a. Energy transfer is terminated when the first battery cell SOC is equal to the second battery cell SOC.

In another exemplary embodiment, the second battery cell 24b is discharged through a resistor until the first battery cell SOC is equal to the second battery cell SOC. After block 406, the exemplary embodiment 112a is concluded, and the method 100 proceeds as discussed above.

The system 10 and method 100 of the present disclosure offer several advantages. The system 10 and method 100 of the present disclosure take advantage of the relatively linear open-circuit voltage (OCV) vs. state of charge (SOC) curve of the first battery cell 24a to allow for more accurate determination of state of charge of a mixed chemistry battery module while also accounting for variations in rate of state of health (SOH) decay between battery chemistries. By providing active balancing capability using the power electronics module 18, the system 10 and method 100 may be used with many battery configurations, including topside or non-topside buffer configurations. The first embodiment of the power electronics module 18′ allows for dual purpose use of the first DC/DC converter 40 for both active balancing and for supplying power to the low voltage electrical system 32a. The second embodiment of the power electronics module 18″ allows for simultaneous active balancing and supply of power to the low voltage electrical system 32a.

The description of the present disclosure is merely exemplary in nature and variations that do not depart from the gist of the present disclosure are intended to be within the scope of the present disclosure. Such variations are not to be regarded as a departure from the spirit and scope of the present disclosure.

What is claimed is:

1. A method for determining battery cell state of charge (SOC), the method comprising:
determining a first battery cell effective capacity of a first battery cell;
determining a first battery cell SOC of the first battery cell based at least in part on the first battery cell effective capacity;
determining a second battery cell effective capacity of a second battery cell, wherein the second battery cell is electrically connected in series with the first battery cell; and
determining a second battery cell SOC of the second battery cell based at least in part on the first battery cell SOC, the first battery cell effective capacity, and the second battery cell effective capacity.

2. The method of claim 1, wherein determining the first battery cell effective capacity further comprises:
determining a first battery cell state of health (SOH) of the first battery cell; and
determining the first battery cell effective capacity using a formula:
$${C}_{1}^{′} = {C}_{1} * {SOH}_{{C}_{1}}$$
wherein C′₁ is the first battery cell effective capacity, C₁ is a first battery cell nominal capacity, and SOH_{C}_{₁} is the first battery cell SOH.

3. The method of claim 2, wherein determining the first battery cell SOH further comprises:
measuring an amount of charge transferred to or from the first battery cell while a voltage of the first battery cell changes from a first reference voltage to a second reference voltage; and
calculating the first battery cell SOH using a formula:
$${SOH}_{{C}_{1}} = \frac{Δ {AH}_{1}^{′}}{Δ {AH}_{1}}$$
wherein SOH_{C}_{₁} is the first battery cell SOH, ΔAH′₁ is the amount of charge transferred to or from the first battery cell, and ΔAH₁ is a reference amount of charge.

4. The method of claim 1, wherein determining the first battery cell SOC further comprises:
measuring a first battery cell voltage of the first battery cell; and
determining the first battery cell SOC using a SOC estimation algorithm, wherein the SOC estimation algorithm is configured to receive at least the first battery cell voltage and the first battery cell effective capacity as inputs and provide the first battery cell SOC as an output.

5. The method of claim 1, wherein determining the second battery cell effective capacity further comprises:
charging the first battery cell and the second battery cell until the second battery cell is fully charged;
determining an amount of charge stored in the first battery cell based on the first battery cell effective capacity and the first battery cell SOC; and
determining the second battery cell effective capacity using a formula:
$${C}_{2}^{′} = {AH}_{1} - {C}_{d}$$
wherein C′₂ is the second battery cell effective capacity, AH₁ is the amount of charge stored in the first battery cell, and C_{d} is a capacity remaining in the first battery cell when the second battery cell is fully discharged.

6. The method of claim 1, wherein determining the second battery cell SOC further comprises:
determining the second battery cell SOC using a formula:
$${SOC}_{{C}_{2}} = \frac{{SOC}_{{C}_{1}} * {C}_{1}^{′} - {C}_{d}}{{C}_{2}^{′}}$$
wherein SOC_{C}_{₁} is the second battery cell SOC, SOC_{C}_{₁} is the first battery cell SOC, C′₁ is the first battery cell effective capacity, C_{d} is a capacity remaining in the first battery cell when the second battery cell is fully discharged, and C′₂ is the second battery cell effective capacity.

7. The method of claim 1, further comprising:
balancing the first battery cell and the second battery cell using an active balancing circuit.

8. The method of claim 7, wherein balancing the first battery cell and the second battery cell further comprises:
comparing the first battery cell SOC to the second battery cell SOC;
transferring energy from the first battery cell to the second battery cell in response to determining that the second battery cell SOC is less than the first battery cell SOC; and
transferring energy from the second battery cell to the first battery cell in response to determining that the first battery cell SOC is less than the second battery cell SOC.

9. The method of claim 7, wherein determining the second battery cell SOC further comprises:
determining a capacity remaining in the first battery cell when the second battery cell is fully discharged based at least in part on the first battery cell effective capacity and the second battery cell effective capacity using a formula:
$${C}_{d}^{′} = {C}_{1}^{′} - {C}_{2}^{′}$$
wherein C′_{d} is the capacity remaining in the first battery cell when the second battery cell is fully discharged, C′₁ is the first battery cell effective capacity, and C′₂ is the second battery cell effective capacity.

10. The method of claim 7, wherein determining the second battery cell SOC further comprises:
determining the second battery cell SOC using a formula:
$${SOC}_{{C}_{2}} = \frac{{SOC}_{{C}_{1}} * {C}_{1}^{′} - {C}_{d}^{′}}{{C}_{2}^{′}}$$
wherein SOC_{C}_{₁} is the second battery cell SOC, SOC_{C}_{₁} is the first battery cell SOC, C′₁ is the first battery cell effective capacity, C′_{d} is a capacity remaining in the first battery cell when the second battery cell is fully discharged, and C′₂ is the second battery cell effective capacity.

11. A system for determining battery cell state of charge (SOC), the system comprising:
a first battery cell having a first cell chemistry;
a second battery cell electrically connected in series with the first battery cell, wherein the second battery cell has a second cell chemistry, and wherein the second cell chemistry is different from the first cell chemistry;
a power electronics module in electrical communication with the first battery cell and the second battery cell, wherein the power electronics module includes one or more electrical components operable to measure voltage and current flow;
a controller in electrical communication with the power electronics module, wherein the controller is programmed to:
determine a first battery cell effective capacity of the first battery cell;
determine a first battery cell SOC of the first battery cell based at least in part on the first battery cell effective capacity;
determine a second battery cell effective capacity of the second battery cell; and
determine a second battery cell SOC of the second battery cell based at least in part on the first battery cell SOC, the first battery cell effective capacity, and the second battery cell effective capacity.

12. The system of claim 11, wherein to determine the first battery cell SOC, the controller is further programmed to:
measure a first battery cell voltage of the first battery cell using the power electronics module; and
determine the first battery cell SOC using a SOC estimation algorithm, wherein the SOC estimation algorithm is configured to receive at least the first battery cell voltage and the first battery cell effective capacity as inputs and provide the first battery cell SOC as an output.

13. The system of claim 12, wherein to determine the second battery cell effective capacity, the controller is further programmed to:
charge the first battery cell and the second battery cell until the second battery cell is fully charged using the power electronics module;
determine an amount of charge stored in the first battery cell based on the first battery cell effective capacity and the first battery cell SOC; and
determine the second battery cell effective capacity using a formula:
$${C}_{2}^{′} = {AH}_{1} - {C}_{d}$$
wherein C′₂ is the second battery cell effective capacity, AH₁ is the amount of charge stored in the first battery cell, and C_{d} is a capacity remaining in the first battery cell when the second battery cell is fully discharged.

14. The system of claim 13, wherein to determine the second battery cell SOC, the controller is further programmed to:
determine the second battery cell SOC using a formula:
$${SOC}_{{C}_{2}} = \frac{{SOC}_{{C}_{1}} * {C}_{1}^{′} - {C}_{d}}{{C}_{2}^{′}}$$
wherein SOC_{C}_{₁} is the second battery cell SOC, SOC_{C}_{₁} is the first battery cell SOC, C′₁ is the first battery cell effective capacity, C_{d} is a capacity remaining in the first battery cell when the second battery cell is fully discharged, and C′₂ is the second battery cell effective capacity.

15. The system of claim 11, wherein:
the power electronics module further comprises:
a DC/DC converter;
a plurality of electrical switches in electrical communication with the DC/DC converter, the first battery cell, the second battery cell, and the controller, wherein an operation of each of the plurality of electrical switches is electrically controllable by the controller; and
the controller is further programmed to:
compare the first battery cell SOC to the second battery cell SOC;
adjust the operation of one or more of the plurality of switches to transfer energy from the first battery cell to the second battery cell using the DC/DC converter in response to determining that the second battery cell SOC is less than the first battery cell SOC; and
adjust the operation of one or more of the plurality of switches to transfer energy from the second battery cell to the first battery cell using the DC/DC converter in response to determining that the first battery cell SOC is less than the second battery cell SOC.

16. The system of claim 15, wherein to determine the second battery cell SOC, the controller is further programmed to:
determine a capacity remaining in the first battery cell when the second battery cell is fully discharged based at least in part on the first battery cell effective capacity and the second battery cell effective capacity using a formula:
$${C}_{d}^{′} = {C}_{1}^{′} - {C}_{2}^{′}$$
wherein C′_{d} is the capacity remaining in the first battery cell when the second battery cell is fully discharged, C′₁ is the first battery cell effective capacity, and C′₂ is the second battery cell effective capacity.

17. The system of claim 16, wherein to determine the second battery cell SOC, the controller is further programmed to:
determine the second battery cell SOC using a formula:
$${SOC}_{{C}_{2}} = \frac{{SOC}_{{C}_{1}} * {C}_{1}^{′} - {C}_{d}^{′}}{{C}_{2}^{′}}$$
wherein SOC_{C}_{₁} is the second battery cell SOC, SOC_{C}_{₁} is the first battery cell SOC, C′₁ is the first battery cell effective capacity, C′_{d} is a capacity remaining in the first battery cell when the second battery cell is fully discharged, and C′₂ is the second battery cell effective capacity.

18. A method for determining battery cell state of charge (SOC) for a vehicle, the method comprising:
determining a first battery cell state of health (SOH) of a first battery cell; and
determining a first battery cell effective capacity using a formula:
$${C}_{1}^{′} = {C}_{1} * {SOH}_{{C}_{1}}$$
wherein C′₁ is the first battery cell effective capacity and SOH_{C}_{₁} is the first battery cell SOH;
charging the first battery cell and a second battery cell until the second battery cell is fully charged;
determining a first battery cell SOC of the first battery cell when the second battery cell is fully charged based at least in part on the first battery cell effective capacity;
determining an amount of charge stored in the first battery cell when the second battery cell is fully charged based on the first battery cell effective capacity and the first battery cell SOC; and
determining a second battery cell effective capacity using a formula:
$${C}_{2}^{′} = {AH}_{1} - {C}_{d}$$
wherein C′₂ is the second battery cell effective capacity, AH₁ is the amount of charge stored in the first battery cell, and C_{d} is a capacity remaining in the first battery cell when the second battery cell is fully discharged, and wherein the second battery cell is electrically connected in series with the first battery cell;
determining a second battery cell SOC of the second battery cell based at least in part on the first battery cell SOC, the first battery cell effective capacity, and the second battery cell effective capacity; and
balancing the first battery cell and the second battery cell.

19. The method of claim 18, wherein determining the second battery cell SOC further comprises:
determining a capacity remaining in the first battery cell when the second battery cell is fully discharged based at least in part on the first battery cell effective capacity and the second battery cell effective capacity using a formula:
$${C}_{d}^{′} = {C}_{1}^{′} - {C}_{2}^{′}$$
wherein C′_{d} is the capacity remaining in the first battery cell when the second battery cell is fully discharged, C′₁ is the first battery cell effective capacity, and C′₂ is the second battery cell effective capacity; and
determining the second battery cell SOC using a formula:
$${SOC}_{{C}_{2}} = \frac{{SOC}_{{C}_{1}} * {C}_{1}^{′} - {C}_{d}^{′}}{{C}_{2}^{′}}$$
wherein SOC_{C}_{₁} is the second battery cell SOC, SOC_{C}_{₁} is the first battery cell SOC, C′₁ is the first battery cell effective capacity, C′_{d} is a capacity remaining in the first battery cell when the second battery cell is fully discharged, and C′₂ is the second battery cell effective capacity.

20. The method of claim 19, wherein balancing the first battery cell and the second battery cell further comprises:
comparing the first battery cell SOC to the second battery cell SOC;
transferring energy from the first battery cell to the second battery cell in response to determining that the second battery cell SOC is less than the first battery cell SOC; and
transferring energy from the second battery cell to the first battery cell in response to determining that the first battery cell SOC is less than the second battery cell SOC.
